(19) United States
(12) Patent Application Publication
(10) Pub. No.: US 2026/0068299 A1
(43) Pub. Date: Mar. 5, 2026

(54) CONTACT CONFIGURATIONS FOR FORKSHEET DEVICES

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Min Gyu Sung, Latham, NY (US)

(21) Appl. No.: 18/816,343

(22) Filed: Aug. 27, 2024

(51) Int. Cl. H01L 27/092; H01L 21/8238; H01L 29/06; H01L 29/417; H01L 29/423; H01L 29/66; H01L 29/775; H01L 29/786

(52) U.S. Cl. CPC H10D 84/85; H10D 30/014; H10D 30/43; H10D 30/6729; H10D 30/6735; H10D 30/6757; H10D 62/121; H10D 84/0188; H10D 84/038

(57) ABSTRACT

A semiconductor device includes a first forksheet transistor structure comprising a first plurality of channel layers connected to a first dielectric bar, a first source/drain region, and a first source/drain contact, where the first source/drain contact contacts a top surface, a side surface, and a bottom surface of the first source/drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming contact configurations for forksheet devices.

In one embodiment, a semiconductor device includes a first forksheet transistor structure comprising a first plurality of channel layers connected to a first dielectric bar, a first source/drain region, and a first source/drain contact, wherein the first source/drain contact contacts a top surface, a side surface, and a bottom surface of the first source/drain region.

In another embodiment, a semiconductor device includes a first forksheet transistor structure comprising a first source/drain region and a first source/drain contact, a second forksheet transistor structure comprising a second source/drain region and a second source/drain contact, and a dielectric bar connected to the first forksheet transistor structure and the second forksheet transistor structure. The first source/drain contact contacts at least three surfaces of the first source/drain region, and the second source/drain contact contacts at least three surfaces of the second source/drain region.

In yet another embodiment, a method includes forming a forksheet transistor structure comprising a dielectric bar, a first source/drain region and a second source/drain region, where a respective first side surface of each the first source/drain region and the second source/drain region are connected to the dielectric bar. The method includes performing a frontside processing step to expose a top surface and top portions of a second side surface of each of the first source/drain region and the second source/drain region, depositing one or more first metal layers to cover the exposed top surfaces and the top portions of the second side surfaces, and forming a cut region by removing at least portions of the one or more first metal layers above a top surface of the dielectric bar and a portion of the dielectric bar, where the cut region extends into and between the first source/drain region and the second source/drain region. The method also includes filling the cut region with a dielectric fill, performing a backside processing step to expose at least a bottom surface and bottom portions of a second side surface of each of the first source/drain region and the second source/drain region, and depositing one or more second metal layers, where the one or more first metal layers and the one or more second metal layers form wrap-around metal contact regions around the top surfaces, second side surfaces, and bottom surfaces of the respective first and second source/drain regions.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X, Y1, and Y2 cross-section locations on which the cross-sectional views of FIGS. 2A-19B are based.

FIG. 2A depicts a first cross-sectional view corresponding to line X in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line Y1 in FIG. 1 illustrating the semiconductor structure of FIG. 1 during the intermediate step of a method of fabricating a nanosheet transistor structure, according to an illustrative embodiment.

FIG. 2C depicts a second cross-sectional view corresponding to line Y2 in FIG. 1 illustrating the semiconductor structure of FIG. 1 during the intermediate step of a method of fabricating a nanosheet transistor structure, according to an illustrative embodiment.

FIG. 3A depicts a first cross-sectional view corresponding to the line X in FIG. 1 following inter-layer dielectric (ILD) layer formation and chemical mechanical planarization (CMP), according to an illustrative embodiment.

FIG. 3B depicts a second cross-sectional view corresponding to the line Y1 in FIG. 1 following the ILD layer formation and CMP, according to an illustrative embodiment.

FIG. 3C depicts a third cross-sectional view corresponding to the line Y2 in FIG. 1 following the ILD layer formation and CMP, according to an illustrative embodiment.

FIG. 4A depicts a first cross-sectional view corresponding to the line X in FIG. 1 following a channel cut process, according to an illustrative embodiment.

FIG. 4B depicts a second cross-sectional view corresponding to the line Y1 in FIG. 1 following the channel cut process, according to an illustrative embodiment.

FIG. 4C depicts a third cross-sectional view corresponding to the line Y2 in FIG. 1 following the channel cut process, according to an illustrative embodiment.

FIG. 5A depicts a first cross-sectional view corresponding to the line X in FIG. 1 following formation of a dummy gate layer and chemical mechanical polishing (CMP), according to an illustrative embodiment.

FIG. 5B depicts a second cross-sectional view corresponding to the line Y1 in FIG. 1 following formation of the dummy gate layer and CMP, according to an illustrative embodiment.

FIG. 5C depicts a third cross-sectional view corresponding to the line Y2 in FIG. 1 following formation of the dummy gate layer and CMP, according to an illustrative embodiment.

FIG. 6A depicts a first cross-sectional view corresponding to the line X in FIG. 1 following dummy gate layer removal, sacrificial layer removal, a replacement metal gate (RMG) process, and formation of a self-aligned contact (SAC) cap layer, according to an illustrative embodiment.

FIG. 6B depicts a second cross-sectional view corresponding to the line Y1 in FIG. 1 following the dummy gate layer removal, the sacrificial layer removal, the RMG process, and the formation of the SAC cap layer, according to an illustrative embodiment.

FIG. 6C depicts a third cross-sectional view corresponding to the line Y2 in FIG. 1 following the dummy gate layer removal, the sacrificial layer removal, the RMG process, and the formation of the SAC cap layer, according to an illustrative embodiment.

FIG. 7A depicts a first cross-sectional view corresponding to the line X in FIG. 1 following a cut process using an organic planarization layer (OPL), according to an illustrative embodiment.

FIG. 7B depicts a second cross-sectional view corresponding to the line Y1 in FIG. 1 following the cut process using the OPL, according to an illustrative embodiment.

FIG. 7C depicts a third cross-sectional view corresponding to the line Y2 in FIG. 1 following the cut process using the OPL, according to an illustrative embodiment.

FIG. 8A depicts a first cross-sectional view corresponding to the line X in FIG. 1 following an OPL ashing process and placeholder layer formation, according to an illustrative embodiment.

FIG. 8B depicts a second cross-sectional view corresponding to the line Y1 in FIG. 1 following the OPL ashing process and the placeholder layer formation, according to an illustrative embodiment.

FIG. 8C depicts a third cross-sectional view corresponding to the line Y2 in FIG. 1 following the OPL ashing process and the placeholder layer formation, according to an illustrative embodiment.

FIG. 9A depicts a first cross-sectional view corresponding to the line X in FIG. 1 following an ILD fill process and CMP, according to an illustrative embodiment.

FIG. 9B depicts a second cross-sectional view corresponding to the line Y1 in FIG. 1 following the ILD fill process and CMP, according to an illustrative embodiment.

FIG. 9C depicts a third cross-sectional view corresponding to the line Y2 in FIG. 1 following the ILD fill process and CMP, according to an illustrative embodiment.

FIG. 10A depicts a first cross-sectional view corresponding to the line X in FIG. 1 following source/drain contact patterning and partial recessing of the placeholder layer, according to an illustrative embodiment.

FIG. 10B depicts a second cross-sectional view corresponding to the line Y1 in FIG. 1 following the source/drain contact patterning and the partial recessing of the placeholder layer, according to an illustrative embodiment.

FIG. 10C depicts a third cross-sectional view corresponding to the line Y2 in FIG. 1 following the source/drain contact patterning and the partial recessing of the placeholder layer, according to an illustrative embodiment.

FIG. 11A depicts a first cross-sectional view corresponding to the line X in FIG. 1 following source/drain contact metallization and a shallow contact cut process, according to an illustrative embodiment.

FIG. 11B depicts a second cross-sectional view corresponding to the line Y1 in FIG. 1 following the source/drain contact metallization and the shallow contact cut process, according to an illustrative embodiment.

FIG. 11C depicts a third cross-sectional view corresponding to the line Y2 in FIG. 1 following the source/drain contact metallization and the shallow contact cut process, according to an illustrative embodiment.

FIG. 12A depicts a first cross-sectional view corresponding to the line X in FIG. 1 following middle-of-line (MOL) contact formation, back-end-of-line (BEOL) interconnect formation, and carrier wafer bonding, according to an illustrative embodiment.

FIG. 12B depicts a second cross-sectional view corresponding to the line Y1 in FIG. 1 following the MOL contact formation, the BEOL interconnect formation, and the carrier wafer bonding, according to an illustrative embodiment.

FIG. 12C depicts a third cross-sectional view corresponding to the line Y2 in FIG. 1 following the MOL contact formation, the BEOL interconnect formation, and the carrier wafer bonding, according to an illustrative embodiment.

FIG. 13A depicts a first cross-sectional view corresponding to the line X in FIG. 1 following wafer flipping and semiconductor substrate removal to an etch stop layer, according to an illustrative embodiment.

FIG. 13B depicts a second cross-sectional view corresponding to the line Y1 in FIG. 1 following the wafer flipping and the semiconductor substrate removal to the etch stop layer, according to an illustrative embodiment.

FIG. 13C depicts a third cross-sectional view corresponding to the line Y2 in FIG. 1 following the wafer flipping and the semiconductor substrate removal to the etch stop layer, according to an illustrative embodiment.

FIG. 14A depicts a first cross-sectional view corresponding to the line X in FIG. 1 following etch stop layer removal, removal of the remaining semiconductor substrate, and backside ILD layer formation, according to an illustrative embodiment.

FIG. 14B depicts a second cross-sectional view corresponding to the line Y1 in FIG. 1 following the etch stop layer removal, the removal of the remaining semiconductor substrate, and the backside ILD layer formation, according to an illustrative embodiment.

FIG. 14C depicts a third cross-sectional view corresponding to the line Y2 in FIG. 1 following the etch stop layer removal, the removal of the remaining semiconductor substrate, and the backside ILD layer formation, according to an illustrative embodiment.

FIG. 15A depicts a first cross-sectional view corresponding to the line X in FIG. 1 following backside contact placeholder removal and selective sacrificial layer removal, according to an illustrative embodiment.

FIG. 15B depicts a second cross-sectional view corresponding to the line Y1 in FIG. 1 following the backside contact placeholder removal and the selective sacrificial layer removal, according to an illustrative embodiment.

FIG. 15C depicts a third cross-sectional view corresponding to the line Y2 in FIG. 1 following the backside contact placeholder removal and the selective sacrificial layer removal, according to an illustrative embodiment.

FIG. 16A depicts a first cross-sectional view corresponding to the line X in FIG. 1 following backside contact formation, according to an illustrative embodiment.

FIG. 16B depicts a second cross-sectional view corresponding to the line Y1 in FIG. 1 following the backside contact formation, according to an illustrative embodiment.

FIG. 16C depicts a third cross-sectional view corresponding to the line Y2 in FIG. 1 following the backside contact formation, according to an illustrative embodiment.

FIG. 17A depicts a first cross-sectional view corresponding to the line X in FIG. 1 following backside interconnect formation, according to an illustrative embodiment.

FIG. 17B depicts a second cross-sectional view corresponding to the line Y1 in FIG. 1 following the backside interconnect formation, according to an illustrative embodiment.

FIG. 17C depicts a third cross-sectional view corresponding to the line Y2 in FIG. 1 following the backside interconnect formation, according to an illustrative embodiment.

FIG. 18A depicts a first cross-sectional view corresponding to the line X in FIG. 1 of a semiconductor structure in accordance with an alternative process, according to an illustrative embodiment.

FIG. 18B depicts a second cross-sectional view corresponding to the line Y1 in FIG. 1 of the semiconductor structure in accordance with the alternative process, according to an illustrative embodiment.

FIG. 18C depicts a third cross-sectional view corresponding to the line Y2 in FIG. 1 of the semiconductor structure in accordance with the alternative process, according to an illustrative embodiment.

FIG. 19A depicts a first cross-sectional view corresponding to the line Y1 in FIG. 1 showing possible cell spacings, according to an illustrative embodiment.

FIG. 19B depicts a second cross-sectional view corresponding to the line Y2 in FIG. 1 showing the possible cell spacings, according to an illustrative embodiment.

### DETAILED DESCRIPTION

Illustrative embodiments may be described herein in the context of illustrative methods for forming contact configurations for forksheet devices, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration. ” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. Forksheet devices, which are also based on GAA architecture, generally comprise channels separated by a dielectric bar. As non-limiting examples, the dielectric bar can separate sets of n-type channels, sets of p-type channels, or a set of n-type channels and a set of p-type channels.

As discussed above, various techniques may be used to reduce the size of FETs, including through the use of fin-shaped channels in FinFET devices, through the use of stacked nanosheet channels formed over a semiconductor substrate, next-generation complementary FET (CFET) devices, and forksheet FET devices.

Although embodiments described herein are discussed in connection with nanosheet stacks, the embodiments are not necessarily limited thereto, and may similarly apply to nanowire stacks.

Conventional techniques for cell height scaling in semiconductor devices can be challenging. For example, cell height scaling in stacked FET devices is impacted by contacts that are needed to wire the top source/drain to the backside or the bottom source/drain to the frontside BEOL interconnects. For forksheet FET devices, one or more gate cuts can be performed after the RMG process. However, cell height for single layer devices is limited by the active region (Rx) size. Conventional techniques generally achieve cell heights of approximately 87 nm and 95 nm for stacked FET and forksheet FET devices, respectively. Utilizing tall forksheet FET devices can help reduce scale cell height by reducing Rx sizes. However, such devices often struggle with high source/drain resistance.

Some embodiments described herein provide a forked sheet structure with wrap-around frontside and backside source/drain contacts. Such embodiments can help address the source/drain resistance issue associated with tall forksheet devices and reduce Rx sizes, thereby leading to improved cell height scaling relative to conventional techniques.

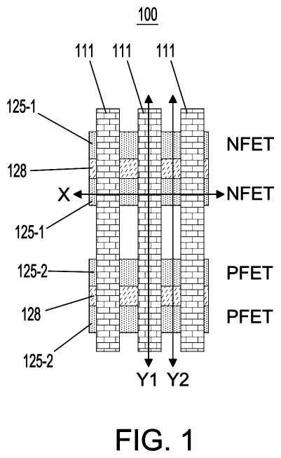

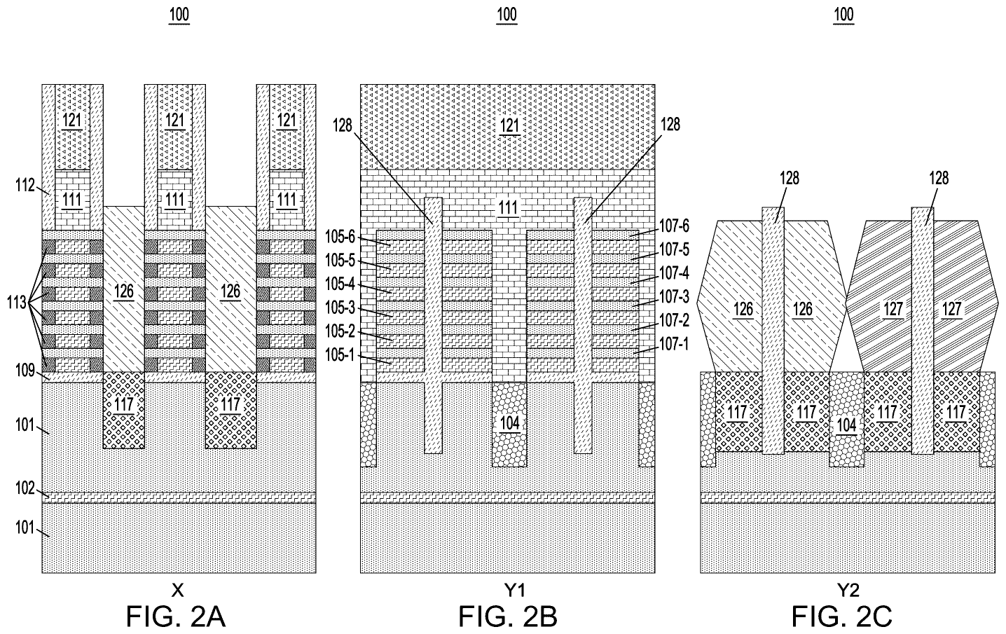

FIG. 1 illustrates a top view of a semiconductor structure 100 with lines X, Y1, and Y2 on which the cross-sectional views of FIGS. 2A-15C are based, according to an illustrative embodiment. Referring also to the cross-sectional views in FIGS. 2A, 2B, and 2C, these figures depict the semiconductor structure 100 during an intermediate fabrication step following patterning of active regions 125-1 and 125-2 (collectively active regions 125), formation of isolation regions 104 (e.g., shallow trench isolation (STI) regions), dummy gate portions 111, gate spacers 112, bottom dielectric isolation (BDI) layer 109, stacked structures comprising sacrificial layers 105-1, 105-2, 105-3, 105-4, 105-5, and 105-6 (collectively “sacrificial layers 105”) and channel layers 107-1, 107-2, 107-3, 107-4, 107-5, and 107-6 (collectively “channel layers 107”), inner spacers 113, a hardmask (HM) layer 121, a backside contact placeholder layer 117, source/drain regions 126 and 127, and dielectric bars 128.

In some embodiments, the active regions 125 correspond to source/drain regions of respective transistors. For example, the active region 125-1 can correspond to the source/drain region 126 of an n-type transistor, and the active region 125-2 can correspond to the source/drain region 127 of a p-type transistor.

In illustrative embodiments, the sacrificial layers 105 comprise SiGe, and the channel layers 107 comprise silicon. In an illustrative embodiment, the sacrificial layers 105 comprise a germanium concentration of about 25% (for example, SiGe25), but the embodiments are not necessarily limited to SiGe25 for the sacrificial layers 105.

While six sacrificial layers 105 and six channel layers 107 are shown, embodiments described herein are not necessarily limited to the shown number of sacrificial layers 105 and channel layers 107, and there may be more or less layers in the same alternating configuration depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials such as Si, SiGe, silicon germanium carbide (SiGeC), silicon carbide (SiC), and multi-layers thereof. Although silicon is the predominantly used semiconductor material in wafer fabrication, alternative semiconductor materials can be employed as additional layers such as, but not limited to, germanium (Ge), gallium arsenide (GaAs), gallium nitride (GaN), SiGe, cadmium telluride (CdTe), and zinc selenide (ZnSe).

As used herein, “frontside” or “first side” refers to a side on top of the semiconductor substrate 101 and/or in front of, on top of, or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

An etch stop layer 102 is formed in the semiconductor substrate 101. The etch stop layer 102 may comprise a buried oxide (BOX) layer or SiGe, or another suitable material such as a III-V semiconductor epitaxial layer.

The isolation regions 104 are formed between the stacked structures comprising the sacrificial layers 105 and the channel layers 107, the BDI layer 109, and the semiconductor substrate 101. In illustrative embodiments, the isolation regions 104 can comprise a dielectric material. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

In some embodiments, the backside contact placeholder layer 117 can be formed by performing a first removal process to remove portions of the BDI layer 109 between the stacked structures comprising the sacrificial layers 105 and the channel layers 107. Following the removal of the exposed portions of the BDI layer 109, a second removal process can remove underlying portions of the semiconductor substrate 101, such that portions of the semiconductor substrate 101 are recessed to create trenches in the semiconductor substrate 101. The semiconductor substrate 101 can be etched using, for example, a tetramethyl ammonium hydroxide (TMAH) solution, to selectively remove SiGe having a relatively higher percentage of germanium, or CF₄ gas to selectively remove SiGe having a relatively lower percentage of germanium. The exposed portions of the semiconductor substrate 101 are recessed below the bottom surfaces of the remaining portions of the BDI layer 109.

The trenches are filled with sacrificial materials to form the backside contact placeholder layer 117. The source/drain regions 126 and 127 can also be formed. In illustrative embodiments, the backside contact placeholder layer 117 can comprise, for example, SiGe, III-V semiconductor material, or other semiconductor materials. The backside contact placeholder layer 117 and the source/drain regions 126 and 127 can be epitaxially grown in a bottom-up epitaxial growth process. For example, the backside contact placeholder layer 117 can be grown from the exposed portions of the semiconductor substrate 101, and the source/drain regions 126 and 127 can be epitaxially grown from the exposed surfaces of the corresponding portions of the backside contact placeholder layer 117.

The dielectric bars 128 extend across and down into the stacked structures comprising the sacrificial layers 105 and the channel layers 107, down into the semiconductor substrate 101, as shown in FIG. 1 and FIGS. 2B and 2C. The dielectric bars 128 can be formed using similar removal processes as used for the backside contact placeholder layer 117, followed by a dielectric material backfill process.

The dummy gate portions 111 are formed on the uppermost channel layers 107-6, around the top portions of the dielectric bars 128, and around the stacked structures comprising the sacrificial layers 105 and the channel layers 107, as shown. The dummy gate portions 111 include but are not limited to an amorphous silicon (a-Si) layer. The dummy gate portions 111 are deposited using deposition techniques such as, for example, CVD, PECVD, RFCVD, PVD, ALD, MBD, PLD, LSMCD, sputtering, and/or plating, followed by a planarization process, such as CMP, and lithography and etching steps to remove excess dummy gate material, and pattern the deposited layer.

The HM layer 121 is formed on the dummy gate portions 111 using any conventional deposition technique such as PVD, ALD, CVD, etc., followed by a planarization step such as a CMP process. The HM layer 121 can be formed of any suitable material such as, for example, amorphous silicon, or another suitable material.

The gate spacers 112 are formed on sides of the HM layer 121 and dummy gate portions 111 by one or more of the deposition techniques noted in connection with deposition of the dummy gate material. The spacer material can comprise, for example, one or more dielectrics, such as but not limited to, SiN, SiON, SiOC, SiCN, BN, SiBN, SiBCN, SiOCN, SiOₓ, and combinations thereof. According to an embodiment, the HM layer 121 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN. Like the gate spacers 112, the inner spacers 113 can be formed by any suitable techniques such as deposition followed by directional etching.

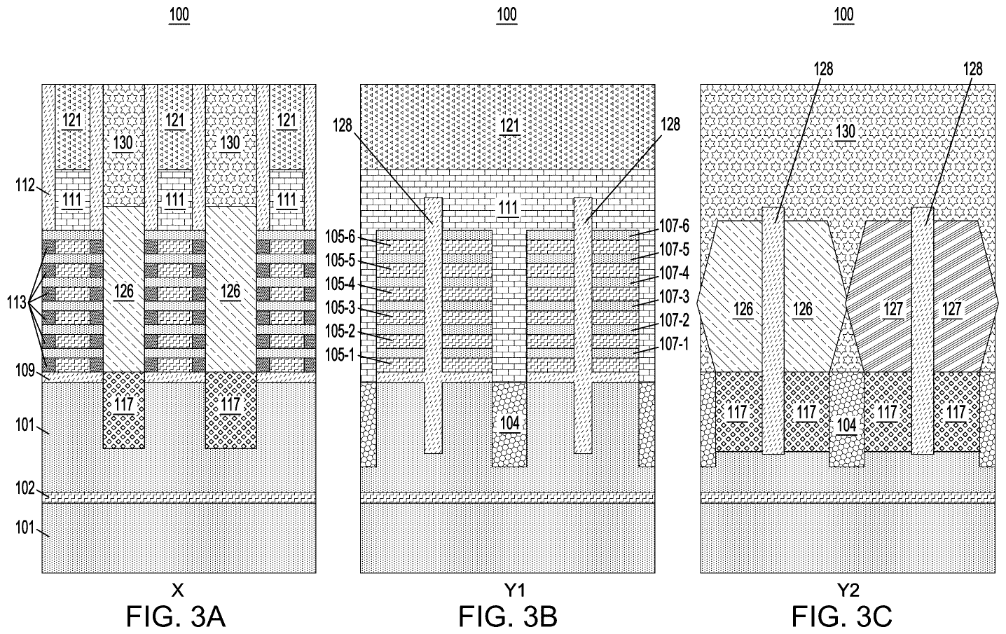

Referring to FIGS. 3A-3C, an ILD layer 130 is deposited to fill in portions on and around the exposed portions of the dielectric bars 128, gate spacers 112, the isolation regions 104, and the source/drain regions 126 and 127. The ILD layer 130 is deposited using deposition techniques such as, for example, CVD, PECVD, RFCVD, PVD, ALD, MBD, PLD, and/or LSMCD, followed by a planarization process, such as CMP, to remove excess portions of the ILD layer 130 deposited on the top surfaces of the HM layer 121 and gate spacers 112. The ILD layer 130 may comprise, for example, SiOx, SiOC, SiOCN or some other dielectric.

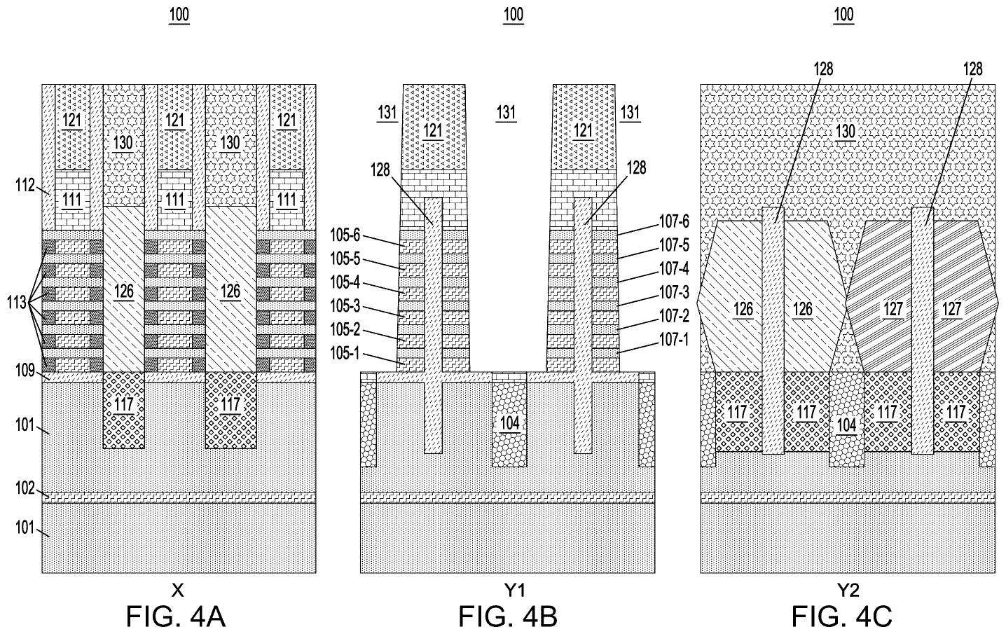

FIGS. 4A-4C show the semiconductor structure 100 following a channel cut process, according to an illustrative embodiment. In some embodiments, the channel cut process can include a mask and patterning process. For example, a dry etch process using a RIE or IBE, a wet chemical etch process, or a combination of these etching processes to remove portions of the HM layer 121, the dummy gate portions 111, and the stacked structures comprising the sacrificial layers 105 and the channel layers 107 down to a level corresponding to the top surface of the BDI layer 109, as shown in FIG. 4B. The channel cut process results in vacant areas 131.

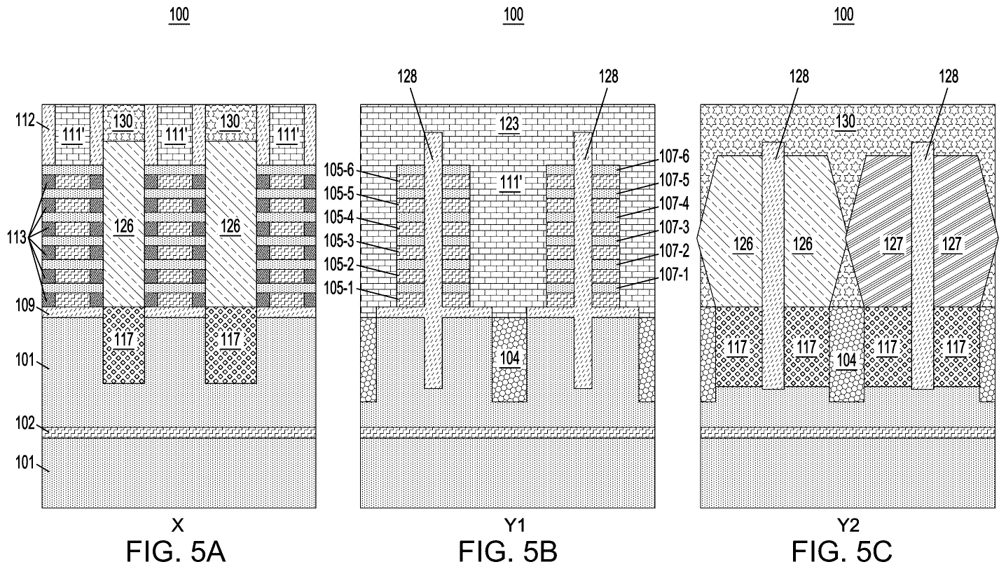

FIGS. 5A-5C show the semiconductor structure 100 following a dummy gate layer fill and CMP processes, according to an illustrative embodiment. The vacant areas 131 are filled with a dummy gate material, thereby forming dummy gate portions 111′. The dummy gate portions 111′ can be formed using similar techniques and materials as described for dummy gate portions 111. In some embodiments, the CMP process can include a polysilicon open CMP (POC) planarization process, which can remove the HM layer 121, portions of the ILD layer 130, and the gate spacers 112.

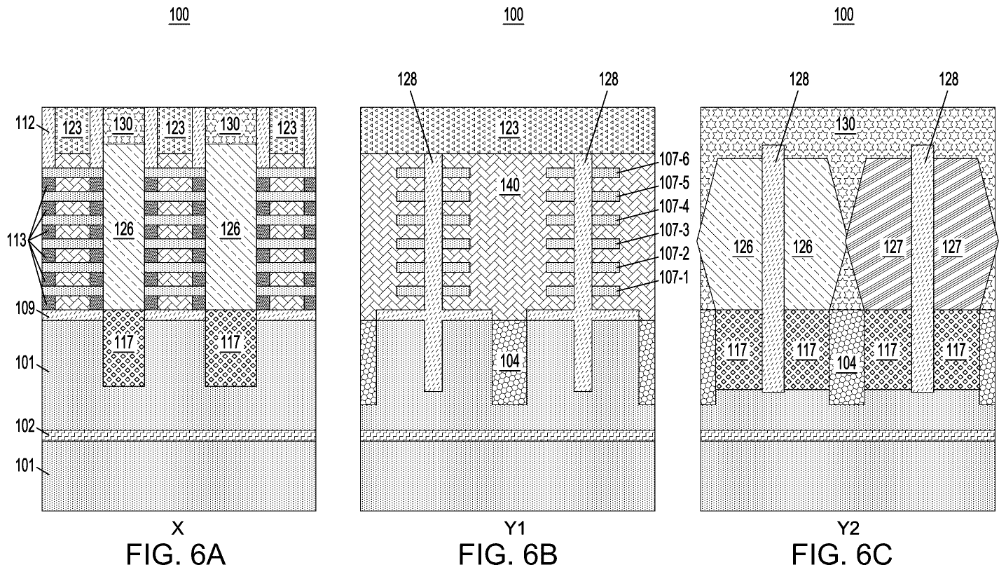

Referring now to FIGS. 6A-6C, the semiconductor structure is shown following removal of the dummy gate portions 111 and the sacrificial layers 105, RMG formation, and formation of a self-aligned contact (SAC) cap layer 123, according to an illustrative embodiment. Specifically, the dummy gate portions 111 and the sacrificial layers 105 are selectively removed to create vacant areas, and gate regions 140 are formed in the vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended, and the gate regions 140, including gate and dielectric portions are formed in the vacant areas left by removal of the dummy gate portions 111 and the sacrificial layers 105. In illustrative embodiments, each of the gate regions 140 includes a gate dielectric layer such as, for example, a high-K dielectric layer such as, but not limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate regions 140 each include a metal gate portion including a work-function metal (WFM) layer. For example, for a pFET, the WFM layer can comprise titanium nitride (TiN), tantalum nitride (TaN) or ruthenium (Ru). For an nFET, the WFM layer can comprise TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN. The metal gate portions can also each further include a gate metal layer such as, but not limited to, metals such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

The SAC cap layer 123 is formed on the top surfaces of the corresponding gate regions 140. The SAC cap layer 123 can comprise silicone (e.g., silicon nitride) or some other suitable capping layer material.

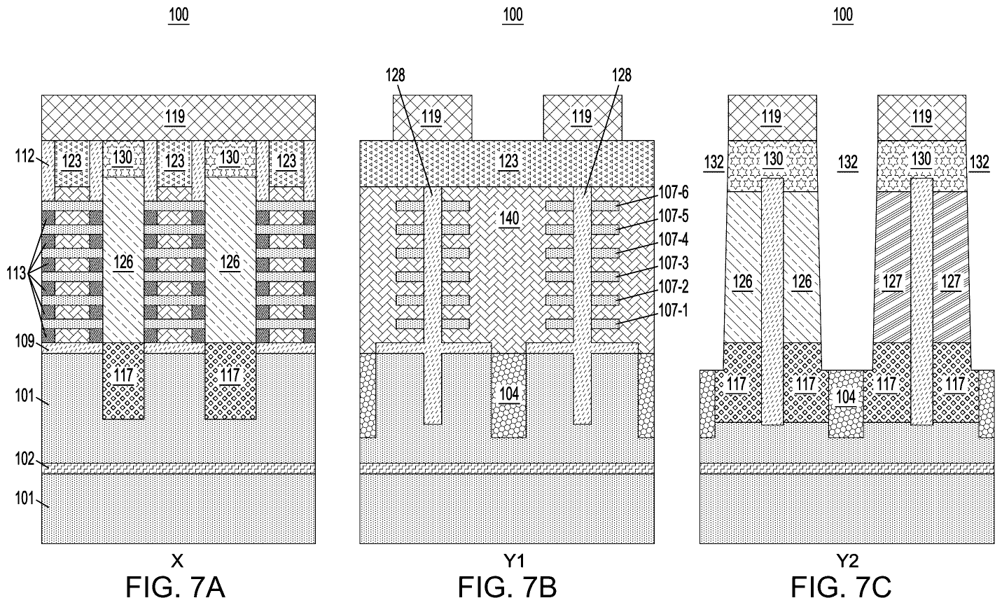

Referring now to FIGS. 7A-7C, the semiconductor structure 100 is shown following a cut process using an organic planarization layer (OPL) 119. The OPL 119 can be deposited on the top surface of the semiconductor structure 100. The OPL 119 can be formed of an organic polymer such as carbon, hydrogen, and/or nitrogen, for example. The OPL 119 can then be patterned to expose areas that are to be recessed, as shown in FIG. 7C. One or more etch processes are subsequently performed to remove portions of the backside contact placeholder layer 117, source/drain regions 126 and 127, ILD layer 130, and isolation regions 104 to form vacant areas 132.

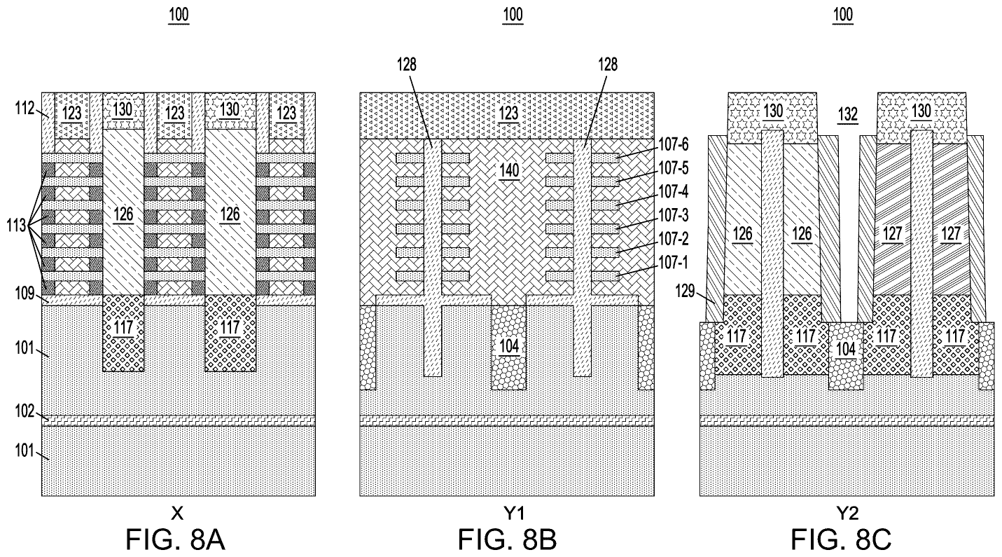

Referring now to FIGS. 8A-8C, the semiconductor structure 100 is shown following an ashing process to remove the OPL 119 and formation of a placeholder layer 129, according to an illustrative embodiment. In some embodiments, the ashing process can strip the OPL 119 using, for example, oxygen plasma, nitrogen/hydrogen plasma or other carbon strip process. The placeholder layer 129 can be epitaxially grown from the backside contact placeholder layer 117 and source/drain regions 126 and 127.

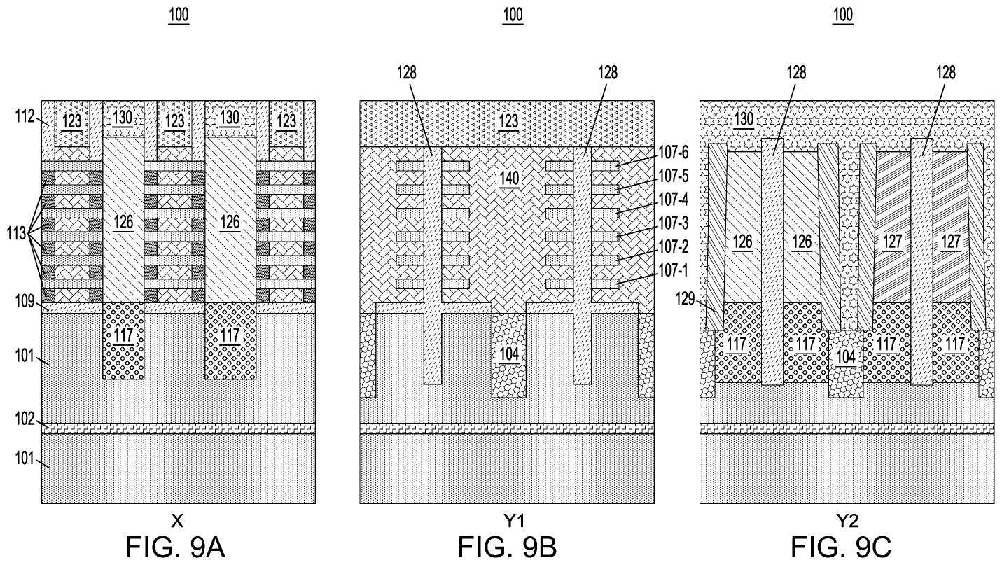

FIGS. 9A-9C depict the semiconductor structure 100 following an ILD fill process and CMP, according to an illustrative embodiment. The remaining portions of the vacant areas 132, following the formation of the placeholder layer 129 are filled with a dielectric material, for example, SiOx, SiOC, SiOCN or some other dielectric. The CMP process removes excess dielectric material, e.g., from the top surfaces of the SAC cap layer 123 and the gate spacers 112.

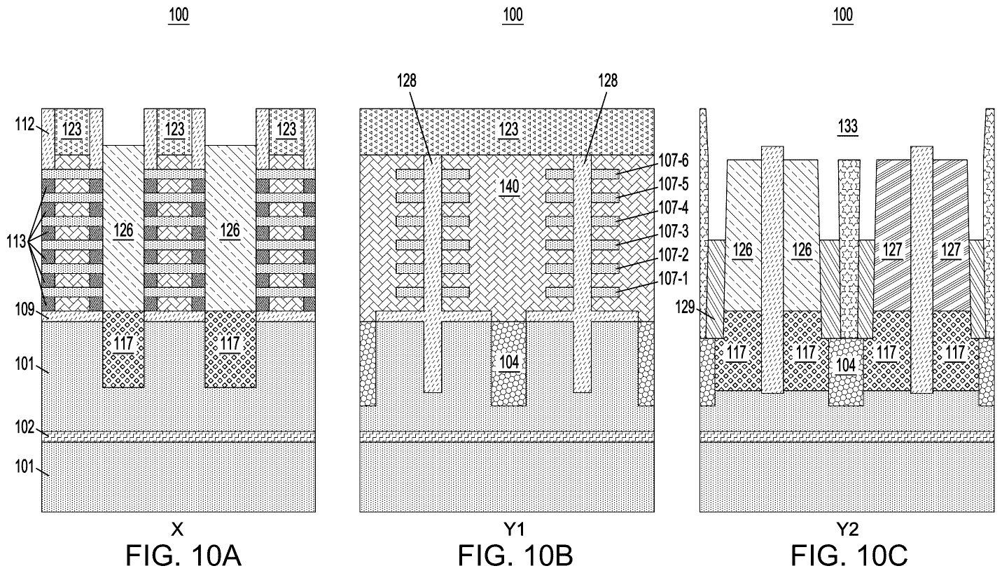

Referring now to FIGS. 10A-10C, the semiconductor structure 100 is shown following source/drain contact patterning and partial recessing of the placeholder layer 129. In some embodiments, the source-drain/contact patterning can include forming masks on parts of the ILD layer 130, and exposed portions of the ILD layer 130 corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

The placeholder layer 129 is then partially removed to create vacant areas 133. Parts of the sidewalls and top surfaces of the dielectric bars 128 and the source/drain regions 126 and 127 are exposed, as shown in FIG. 10C. In some embodiments, the placeholder layer 129 can be removed using one or more selective etching processes such as wet and/or dry etching processes.

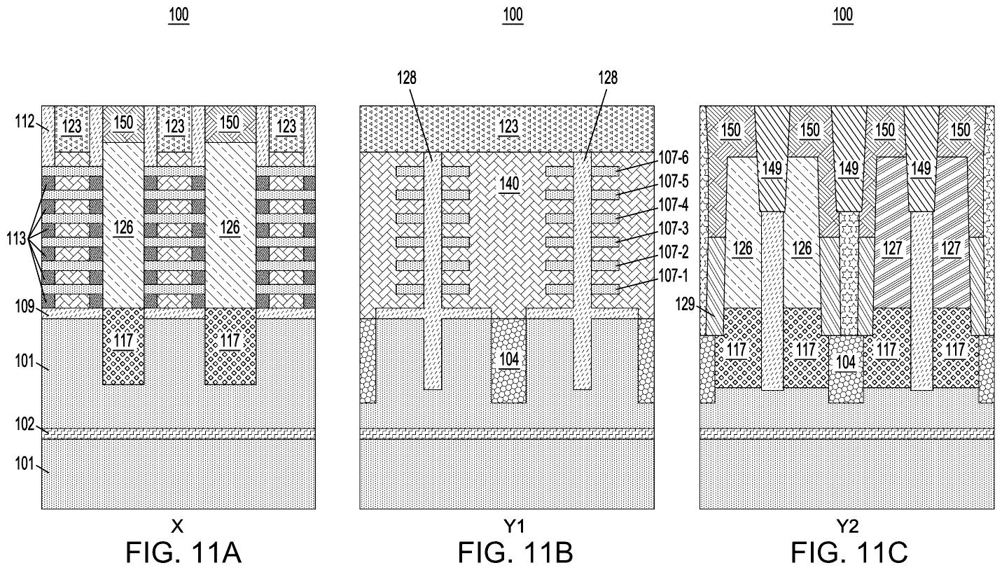

Referring now to FIGS. 11A-11C, the semiconductor structure 100 is shown following source/drain contact metallization and a shallow contact cut process, according to an illustrative embodiment. Frontside metal layers 150 are deposited in the vacant areas 133. The frontside metal layers 150 may correspond to one or more frontside contacts, for example. The frontside metal layers 150 may include a silicide layer such as Ni, Ti, NiPt, etc., a metal adhesion layer, such as TiN, and a conductive metal fill layer such as tungsten (W), aluminum (Al), copper (Cu), cobalt (Co), ruthenium (Ru), molybdenum (Mo), etc., and can be deposited using, for example, a deposition technique such as CVD, PECVD, RFCVD, PVD, ALD, MBD, PLD, LSMCD, sputtering and/or plating, followed by planarization processes, such as CMP, to remove excess portions of the frontside metal layers 150 from on top of the ILD layer 130.

In some embodiments, the shallow contact cut process can include removing portions of the frontside metal layers 150 down to the top surfaces of the dielectric bars 128 and the remaining portion of the ILD layer 130 between the source/drain regions 126 and 127. The shallow contact cut process also includes depositing a dielectric material in the removed portions of the frontside metal layers 150 resulting in dielectric fill regions 149. The frontside metal layers 150 can be etched using, for example, RIE. The dielectric material of the dielectric fill regions 149 is deposited using deposition techniques such as, for example, CVD, PECVD, RFCVD, PVD, ALD, MBD, PLD, and/or LSMCD, followed by a planarization process, such as, CMP. The dielectric material of the dielectric fill regions 149 may comprise, but is not necessarily limited to, SiN, SiC, SiON, SiOC, SiCN, BN, SiBN, SiBCN, SiOCN, SiOₓ, or some other dielectric.

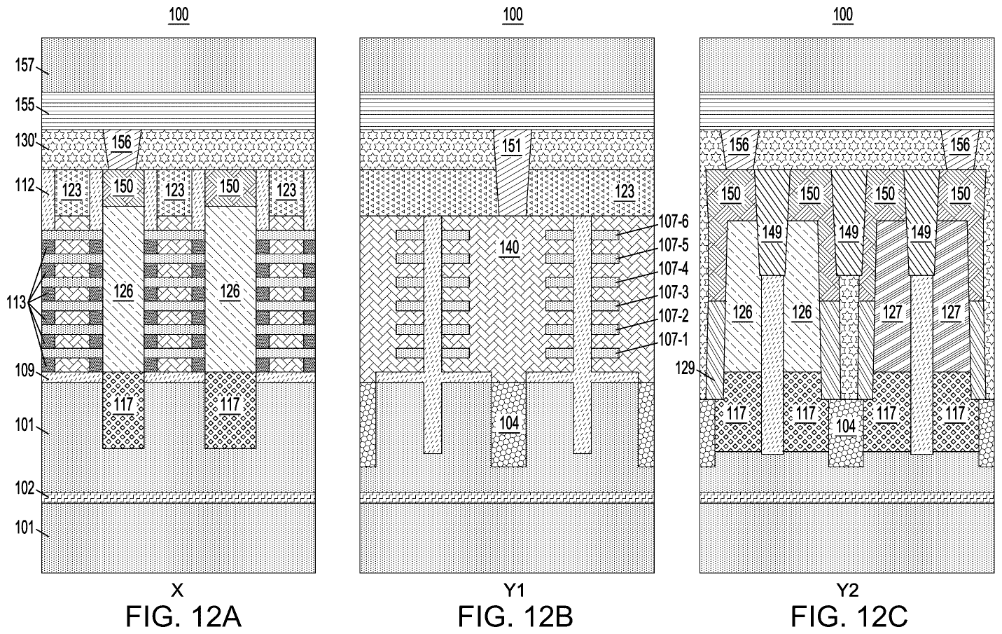

Referring now to FIGS. 12A-12C, the semiconductor structure 100 is shown following middle-of-line (MOL) contact formation, back-end-of-line (BEOL) interconnect formation, and carrier wafer bonding, according to an illustrative embodiment.

Additional ILD material is deposited on the ILD layer 130 and the SAC cap layer 123, thereby forming ILD layer 130′. Frontside source/drain vias 156 are formed in the ILD layer 130′ to contact respective top surfaces of the frontside metal layers 150. According to an embodiment, masks are formed on parts of the ILD layer 130′, and exposed portions of the ILD layer 130′ corresponding to where openings are to be formed are removed using, for example, a dry etching process using a RIE or IBE process, a wet chemical etch process or a combination of these etching processes. The frontside source/drain vias 156 can be formed in the openings to land on and contact the respective top surfaces of the frontside metal layers 150. The material of the frontside source/drain vias 156 can comprise a conductive material such as W, Al, Cu, Co, Ru, Mo, or any other suitable conductive material.

Additionally, at least one frontside gate contact 151 is formed through the ILD layer 130′ and the SAC cap layer 123 to land on and contact a corresponding one of the gate regions 140. The process and materials used for forming the at least one frontside gate contact 151 are similar to those used for forming the frontside source/drain vias 156, for example.

The frontside BEOL interconnects 155 are formed on the ILD layer 130′ and include various BEOL interconnect structures. The frontside source/drain vias 156 can connect corresponding portions of the metal layers 150 and 152 to the frontside BEOL interconnects 155, for example. The carrier wafer 157 may be formed of materials similar to those used in the semiconductor substrate 101 and can be formed over the frontside BEOL interconnects 155 using a wafer bonding process, such as dielectric-to-dielectric bonding.

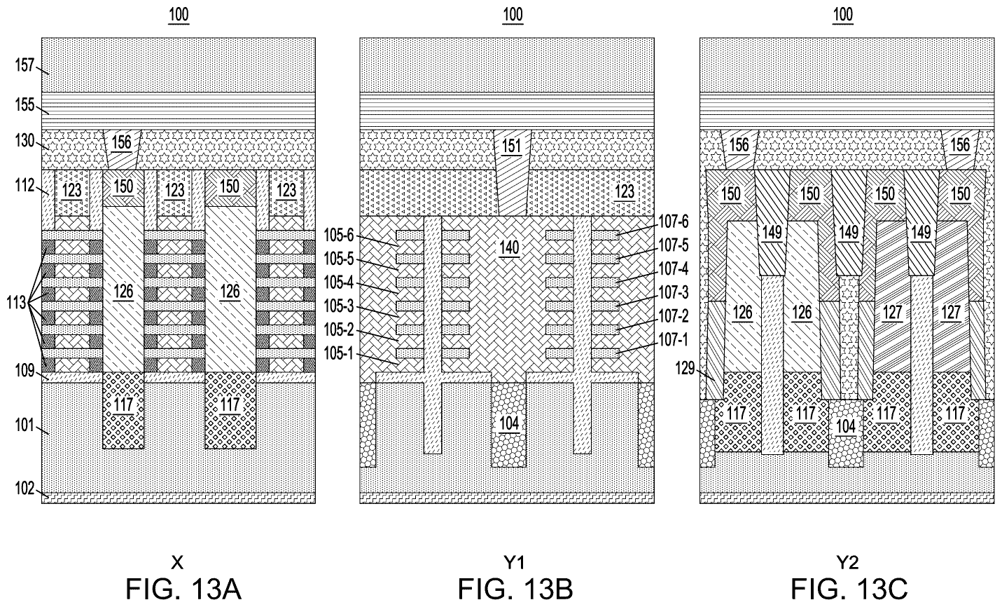

Referring now to FIGS. 13A-13C, using the carrier wafer 157, the semiconductor structure 100 may be “flipped” (for example, rotated 180 degrees) so that the structure is inverted. In addition, the semiconductor substrate 101 is removed from the backside of the semiconductor structure 100 stopping at the etch stop layer 102. For example, the semiconductor substrate 101 can be selectively etched with an etchant that selectively etches silicon with respect to a material of the etch stop layer 102.

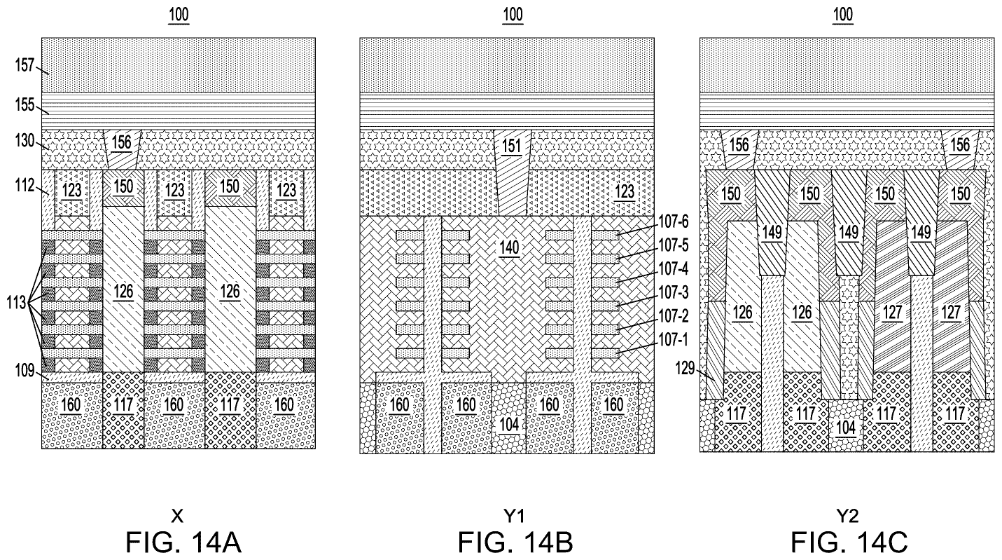

Referring now to FIGS. 14A-14C, the etch stop layer 102 and the remaining semiconductor substrate 101 are removed. The etching processes for removal of the etch stop layer 102 include but are not limited to IBE using Ar/CHF3 based chemistry. Etchants for removing the semiconductor substrate 101 include, for example, potassium hydroxide (KOH) and TMAH. A backside ILD layer 160 is deposited using deposition techniques such as CVD, PECVD, RFCVD, PVD, ALD, MBD, PLD, and/or LSMCD, followed by a planarization process, such as CMP. For example, the planarization process to expose the bottom surfaces of the backside contact placeholder layer 117. The backside ILD layer 160 may comprise, for example, SiOₓ, SiOC, SiOCN or some other dielectric.

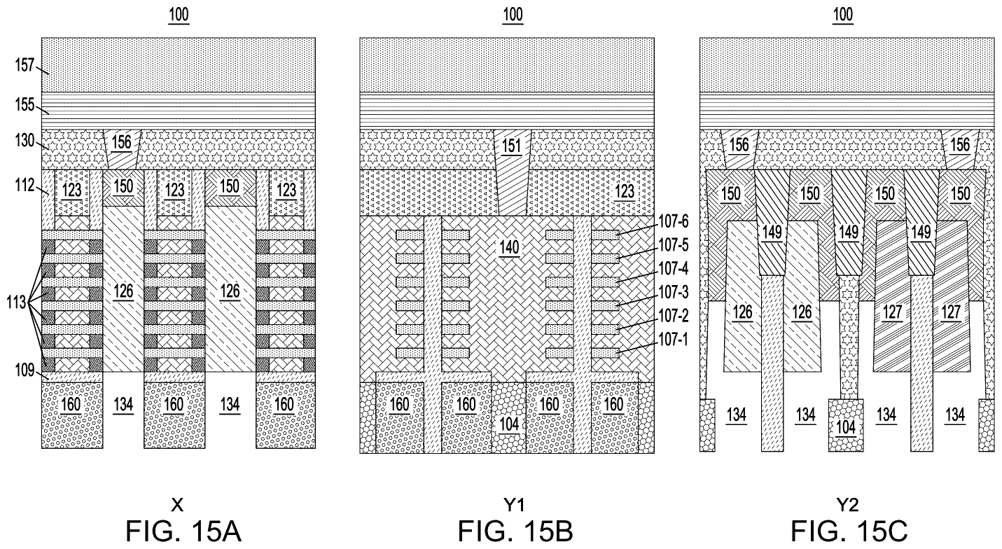

Referring now to FIGS. 15A-15C, the backside contact placeholder layer 117 and the remaining portions of the placeholder layer 129 are removed to form vacant areas 134. For example, the backside contact placeholder layer 117 and the placeholder layer 129 can be selectively removed using a dry etching process such as RIE or IBE, a wet chemical etching process, or a combination of these etching processes.

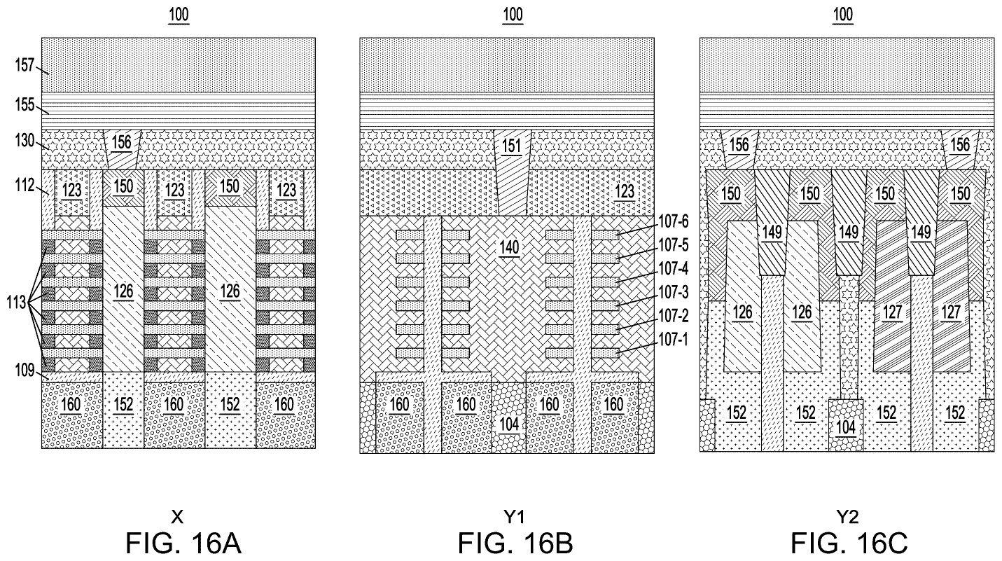

Referring now to FIGS. 16A-16C, the semiconductor structure 100 is shown following formation of backside metal layers 152, according to an illustrative embodiment. The backside metal layers 152 may comprise one or more backside contacts, for example. The backside metal layers 152 are deposited in the vacant areas 134, followed by a planarization process. The material and techniques for forming the backside metal layers 152 may be similar to that of the frontside metal layers 150, for example. The backside metal layers 152 contact respective backside portions of the source/drain regions 126 and 127 and the frontside metal layers 150.

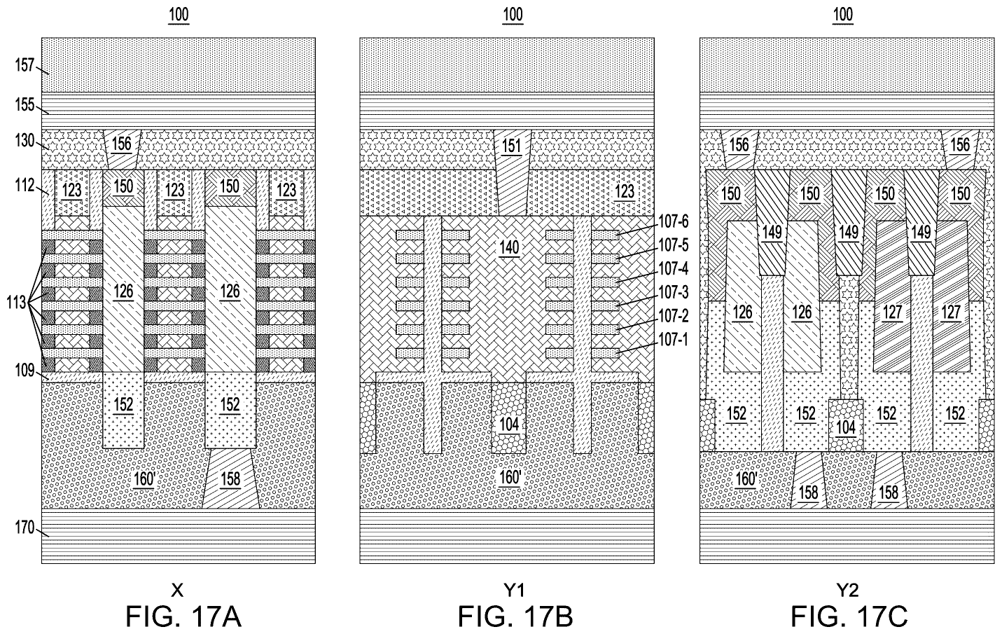

Referring now to FIGS. 17A-17C, the semiconductor structure 100 is shown following backside interconnect formation, according to an illustrative embodiment. Additional ILD material is deposited on the backside ILD layer 160, thereby forming backside ILD layer 160′. Backside source/drain vias 158 are formed in the backside ILD layer 160′ to contact respective bottom surfaces of the backside metal layers 152, as shown in FIGS. 17B and 17C. The backside source/drain vias 158 can be formed using similar processes and materials as the frontside source/drain vias 156.

Backside power delivery network (BSPDN) layers 170 are formed on the backside ILD layer 160 and on the backside source/drain contacts 153. The BSPDN layers 170 can include various backside interconnect structures, such as power delivery network structures including, but not limited to, interconnects in a power supply path from voltage regulator modules (VRMs) to circuits. The interconnect structures can comprise, for example, power and ground planes in circuit boards, cables, connectors, and capacitors associated with a power supply. Backside power delivery prevents BEOL routing congestion, resulting in power performance benefits.

The backside source/drain vias 158 connect corresponding portions of the metal layers 150 and 152 to the BSPDN layers 170. In some embodiments, the BSPDN layers 170 can alternatively or additionally be used for routing of signals, including power and/or clock signals as non-limiting examples.

In at least some embodiments, portions of the frontside metal layers 150 and the backside metal layers 152 form wrap-around metal contacts that surround corresponding portions of top, side, and bottom surfaces of the source/drain regions 126 and 127. The frontside source/drain vias 156 and the corresponding portions of the frontside metal layers 150 and the backside metal layers 152 form frontside source/drain contacts that surround a top, side, and bottom surface of the corresponding source/drain regions 126 and 127.

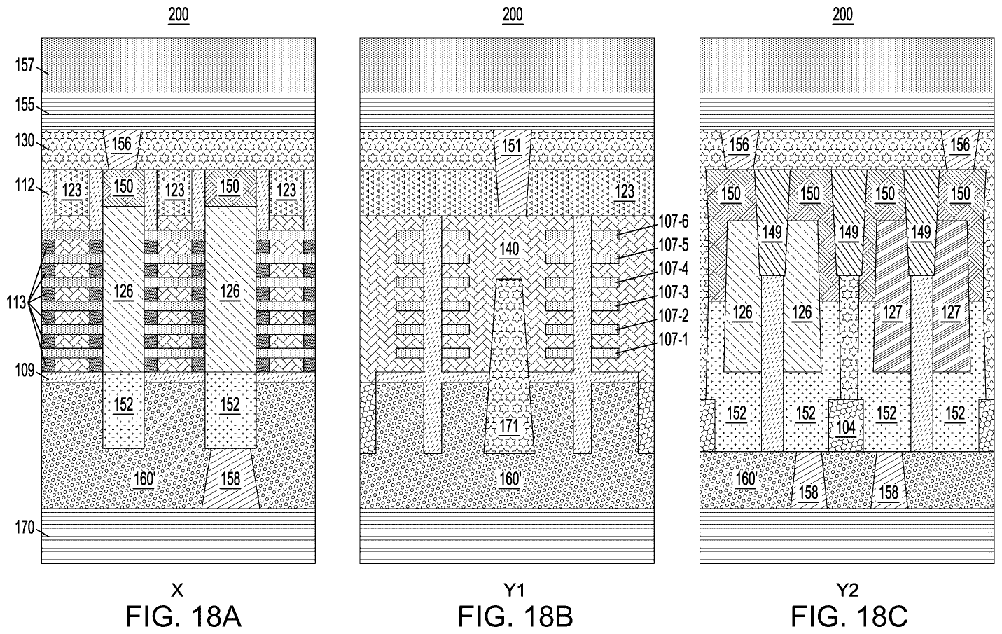

FIGS. 18A-18C depict cross-sectional views, respectively corresponding to lines X, Y1, and Y2 in FIG. 1, of a semiconductor structure 200 in accordance with an alternative process, according to an illustrative embodiment. The semiconductor structure 200 can be formed using similar techniques and materials as described in conjunction with FIGS. 2A-18B for semiconductor structure 100. The semiconductor structure 200 further includes a backside isolation structure 171. In some embodiments, the backside isolation structure 171 can be formed as an additional backside processing step following the removal of the etch stop layer 102 and the remaining semiconductor substrate 101 described in conjunction with FIGS. 13A-13C.

For example, portions of the isolation regions 104 can be removed between the stacked structures comprising the sacrificial layers 105 and the channel layers 107, and then a gate cut process is performed to form an opening corresponding to where the backside isolation structure 171 is to be formed. The gate cut process can be performed using any suitable wet or dry etch process. The backside isolation structure 171 is formed by removing by filling the opening with a dielectric material. The dielectric material of the backside isolation structure 171 can comprise SiOx, SiOC, SiOCN, or some other dielectric. The backside isolation structure 171 reduces the amount of gate material used for the gate regions 140, which can advantageously reduce capacitance.

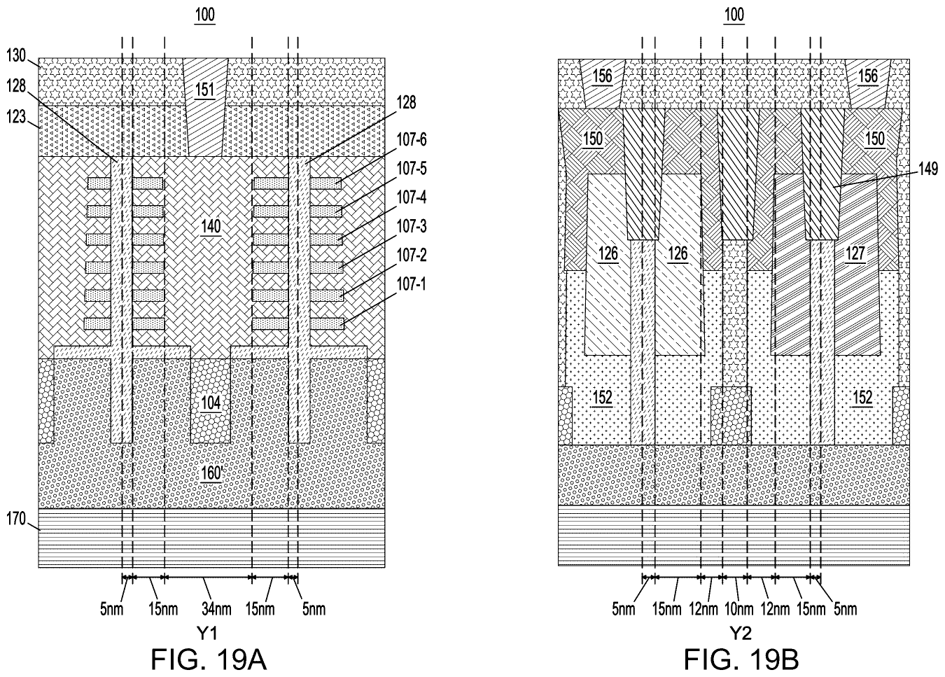

FIGS. 19A-19B depict cross-sectional views corresponding to lines Y1 and Y2 in FIG. 1 showing an example of spacings that can be supported by the semiconductor structure 100, according to an illustrative embodiment. In FIG. 19A, the cell height can be computed based on the distance between the middles of the two dielectric bars 128. Assuming the minimum spacing between the Rx regions is 34 nm, then the semiconductor structure 100 can support a cell height of 74 nm. The cell height can be computed as: 5 nm+15 nm+34 nm+15 nm+5 nm, where the values respectively correspond to a first one of the dielectric bars 128, a first Rx region, the minimum spacing between Rx regions, a second Rx region, and a second one of the dielectric bars 128. FIG. 19B shows the spacing values along the cross-sectional view corresponding to line Y2.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes a first forksheet transistor structure comprising a first plurality of channel layers connected to a first dielectric bar, a first source/drain region, and a first source/drain contact, where the first source/drain contact contacts a top surface, a side surface, and a bottom surface of the first source/drain region.

In embodiments, the semiconductor device may include a second forksheet transistor structure comprising a second plurality of channel layers connected to a second dielectric bar, a second source/drain region, and a second source/drain contact, where the second source/drain contact contacts a top surface, a side surface, and a bottom surface of the second source/drain region.

In embodiments, the first forksheet transistor structure may include one of a p-type transistor device and an n-type transistor device, and wherein the second forksheet transistor structure may include the other one of the p-type transistor device and the n-type transistor device.

In embodiments, the semiconductor device may include a frontside inter-layer dielectric layer, a frontside dielectric structure, and a shallow trench isolation region, where the frontside inter-layer dielectric layer, the frontside dielectric structure, and the shallow trench isolation region are disposed between the first source/drain contact and the second source/drain contact.

In embodiments, the semiconductor device may include at least one gate region that surrounds the first plurality of channel layers and the second plurality of channel layers.

In embodiments, the semiconductor device may include a backside isolation structure that extends from below a level corresponding to a bottom surface of the first forksheet transistor structure and the second forksheet transistor structure and into a portion of the at least one gate region between the first plurality of channel layers and the second plurality of channel layers.

In embodiments, the semiconductor device may include at least one dielectric fill region connected to the first dielectric bar, where the at least one dielectric fill region separates the first source/drain contact from at least one other source/drain contact.

In embodiments, the first source/drain contact may wrap around the top surface, the side surface, and the bottom surface of the first source/drain region.

In embodiments, the first source/drain contact may be connected to a backside power delivery network.

In another embodiment, a semiconductor device includes a first forksheet transistor structure comprising a first source/drain region and a first source/drain contact and a second forksheet transistor structure comprising a second source/drain region and a second source/drain contact. The semiconductor device also includes a dielectric bar connected to the first forksheet transistor structure and the second forksheet transistor structure, where the first source/drain contact contacts at least three surfaces of the first source/drain region, and the second source/drain contact contacts at least three surfaces of the second source/drain region.

In embodiments, the first source/drain contact and the second source/drain contact may be formed with a wrap-around configuration around a top surface, a side surface, and a bottom surface of the respective first and second source/drain regions.

In embodiments, the first source/drain region and the second source/drain region may each include at least one other surface that is connected to the dielectric bar.

In embodiments, the first source/drain contact may be connected to one of a frontside interconnect structure and backside interconnect structure, the second source/drain contact may be connected to the other one of the frontside interconnect structure and the backside interconnect structure.

In embodiments, the backside interconnect structure may include at least a portion of a backside power delivery network.

In embodiments, the semiconductor device may include at least one gate region that surrounds a plurality of channel layers of the first forksheet transistor structure and another plurality of channel layers of at least one third forksheet transistor structure.

In embodiments, the semiconductor device may include a backside isolation structure that extends from below a level corresponding to a bottom surface of the first forksheet transistor structure and the third forksheet transistor structure and into a portion of the at least one gate region between the first forksheet transistor structure and the third forksheet transistor structure.

In yet another embodiment, a method includes forming a forksheet transistor structure comprising a dielectric bar, a first source/drain region and a second source/drain region, where a respective first side surface of each the first source/drain region and the second source/drain region are connected to the dielectric bar. The method includes performing a frontside processing step to expose a top surface and top portions of a second side surface of each of the first source/drain region and the second source/drain region, depositing one or more first metal layers to cover the exposed top surfaces and the top portions of the second side surfaces, and forming a cut region by removing at least portions of the one or more first metal layers above a top surface of the dielectric bar and a portion of the dielectric bar, where the cut region extends into and between the first source/drain region and the second source/drain region. The method also includes filling the cut region with a dielectric fill, performing a backside processing step to expose at least a bottom surface and bottom portions of a second side surface of each of the first source/drain region and the second source/drain region, and depositing one or more second metal layers, where the one or more first metal layers and the one or more second metal layers form wrap-around metal contact regions around the top surfaces, second side surfaces, and bottom surfaces of the respective first and second source/drain regions.

In embodiments, the method further includes forming at least one backside via that connects the wrap-around metal contact region corresponding to one of the first and second source/drain regions to a backside power delivery network.

In embodiments, the method further includes forming at least one frontside via that connects the wrap-around metal contact region corresponding to one of the first and second source/drain regions to at least one frontside interconnect structure.

In embodiments, the method further includes forming a backside isolation structure that extends into a portion of at least one gate region between the forksheet transistor structure and another forksheet transistor structure.

The above-described embodiments advantageously improved configurations for frontside and backside source/drain contacts within a forksheet structure. For example, some embodiments include frontside and backside source/drain contacts that wrap-around the source/drain regions. Such embodiments can help reduce source/drain resistance and reduce the sizes of Rx regions relative to conventional techniques, thereby improving cell height scaling.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first forksheet transistor structure comprising a first plurality of channel layers connected to a first dielectric bar, a first source/drain region, and a first source/drain contact;
wherein the first source/drain contact contacts a top surface, a side surface, and a bottom surface of the first source/drain region.

2. The semiconductor device of claim 1, further comprising:
a second forksheet transistor structure comprising a second plurality of channel layers connected to a second dielectric bar, a second source/drain region, and a second source/drain contact;
wherein the second source/drain contact contacts a top surface, a side surface, and a bottom surface of the second source/drain region.

3. The semiconductor device of claim 2, wherein:
the first forksheet transistor structure comprises one of a p-type transistor device and an n-type transistor device, and wherein the second forksheet transistor structure comprises the other one of the p-type transistor device and the n-type transistor device.

4. The semiconductor device of claim 3, further comprising:
a frontside inter-layer dielectric layer;
a frontside dielectric structure; and
a shallow trench isolation region;
wherein the frontside inter-layer dielectric layer, the frontside dielectric structure, and the shallow trench isolation region are disposed between the first source/drain contact and the second source/drain contact.

5. The semiconductor device of claim 2, further comprising:
at least one gate region that surrounds the first plurality of channel layers and the second plurality of channel layers.

6. The semiconductor device of claim 5, further comprising:
a backside isolation structure that extends from below a level corresponding to a bottom surface of the first forksheet transistor structure and the second forksheet transistor structure and into a portion of the at least one gate region between the first plurality of channel layers and the second plurality of channel layers.

7. The semiconductor device of claim 1, further comprising:
at least one dielectric fill region connected to the first dielectric bar, wherein the at least one dielectric fill region separates the first source/drain contact from at least one other source/drain contact.

8. The semiconductor device of claim 1, wherein the first source/drain contact wraps around the top surface, the side surface, and the bottom surface of the first source/drain region.

9. The semiconductor device of claim 1, wherein the first source/drain contact is connected to a backside power delivery network.

10. A semiconductor device comprising:
a first forksheet transistor structure comprising a first source/drain region and a first source/drain contact;
a second forksheet transistor structure comprising a second source/drain region and a second source/drain contact;
a dielectric bar connected to the first forksheet transistor structure and the second forksheet transistor structure;
wherein the first source/drain contact contacts at least three surfaces of the first source/drain region, and the second source/drain contact contacts at least three surfaces of the second source/drain region.

11. The semiconductor device of claim 10, wherein:
the first source/drain contact and the second source/drain contact are formed with a wrap-around configuration around a top surface, a side surface, and a bottom surface of the respective first and second source/drain regions.

12. The semiconductor device of claim 10, wherein:
the first source/drain region and the second source/drain region each comprise at least one other surface that is connected to the dielectric bar.

13. The semiconductor device of claim 10, wherein:
the first source/drain contact is connected to one of a frontside interconnect structure and backside interconnect structure; and
the second source/drain contact is connected to the other one of the frontside interconnect structure and the backside interconnect structure.

14. The semiconductor device of claim 13, wherein:
the backside interconnect structure comprises at least a portion of a backside power delivery network.

15. The semiconductor device of claim 10, further comprising:
at least one gate region that surrounds a plurality of channel layers of the first forksheet transistor structure and another plurality of channel layers of at least one third forksheet transistor structure.

16. The semiconductor device of claim 15, further comprising:
a backside isolation structure that extends from below a level corresponding to a bottom surface of the first forksheet transistor structure and the third forksheet transistor structure and into a portion of the at least one gate region between the first forksheet transistor structure and the third forksheet transistor structure.

17. A method comprising:
forming a forksheet transistor structure comprising a dielectric bar, a first source/drain region and a second source/drain region, wherein a respective first side surface of each the first source/drain region and the second source/drain region are connected to the dielectric bar;
performing a frontside processing step to expose a top surface and top portions of a second side surface of each of the first source/drain region and the second source/drain region;
depositing one or more first metal layers to cover the exposed top surfaces and the top portions of the second side surfaces;
forming a cut region by removing at least portions of the one or more first metal layers above a top surface of the dielectric bar and a portion of the dielectric bar, wherein the cut region extends into and between the first source/drain region and the second source/drain region;
filling the cut region with a dielectric fill;
performing a backside processing step to expose at least a bottom surface and bottom portions of a second side surface of each of the first source/drain region and the second source/drain region; and
depositing one or more second metal layers, wherein the one or more first metal layers and the one or more second metal layers form wrap-around metal contact regions around the top surfaces, second side surfaces, and bottom surfaces of the respective first and second source/drain regions.

18. The method of claim 17, further comprising:
forming at least one backside via that connects the wrap-around metal contact region corresponding to one of the first and second source/drain regions to a backside power delivery network.

19. The method of claim 17, further comprising:
forming at least one frontside via that connects the wrap-around metal contact region corresponding to one of the first and second source/drain regions to at least one frontside interconnect structure.

20. The method of claim 17, further comprising:
forming a backside isolation structure that extends into a portion of at least one gate region between the forksheet transistor structure and another forksheet transistor structure.
